(19) United States
(12) Patent Application Publication
(10) Pub. No.: US 2025/0040083 A1
(43) Pub. Date: Jan. 30, 2025

(54) IMMERSION COOLING SYSTEM

(71) Applicant: Modine LLC, Racine, WI (US)

(72) Inventors: Edward King, Plano, TX (US); Jacob Mertel, Plano, TX (US); Brian Haught, Plano, TX (US); Ryan Graham, Plano, TX (US); Lillian Turner, Plano, TX (US)

(21) Appl. No.: 18/778,323

(22) Filed: Jul. 19, 2024

Related U.S. Application Data
(60) Provisional application No. 63/529,194, filed on Jul. 27, 2023.

(51) Int. Cl. H05K 7/20

(52) U.S. Cl. CPC H05K 7/20272; H05K 7/20236; H05K 7/20781

(57) ABSTRACT

A cooling system includes a sump area configured to hold a dielectric fluid, a bath area that receives a computer component, a first filter, a second filter, and a pump that draws the dielectric fluid from the sump area, passes the dielectric fluid through at least one of the first filter or the second filter, and delivers the dielectric fluid to the bath area. The bath area holds the dielectric fluid.

### CROSS-REFERENCE TO RELATED APPLICATIONS

This application claims priority to U.S. Provisional Application No. 63/529,194, filed on Jul. 27, 2023, which is related to PCT Publication WO2020/102090, filed on Nov. 11, 2019, the entire contents of each of which are incorporated herein by reference.

### FIELD OF THE DISCLOSURE

The present disclosure relates to processes and systems for utilizing dual filters, clamped lids, and stabilizers in a liquid immersion cooling platform.

### BACKGROUND

Halocarbons such as perflouorocarbon liquid dielectic fluids such as 3M's NOVEC™ are frequently employed in immersion cooling of computer components such as servers. As the dielectric fluid circulates in the system, it washes away various contaminants and debris, which may be harmful to the computer components and/or other aspects of the liquid immersion cooling system. Therefore, it is desirable to incorporate a filter system in the immersion cooling platform to separate these harmful contaminants and debris.

Additionally, in immersion cooling platforms, sometimes it is desirable to swap the computer components. As such, some immersion cooling platforms provide for a lid to enable access to and removal of the computer components. These immersion cooling platforms provide for large lids that are secured using screws to the body of the tank. Therefore, it is desirable to provide for a lid that can be easily removable.

Furthermore, certain immersion cooling platforms can be installed on mobile bodies. In such platforms, the tank can shake and vibrate. It is therefore desirable to minimize any movement impact to the immersion cooling platform and components thereof.

Disclosed herein are filter, lid and stabilization methods and systems for a liquid immersion cooling platform. These and other objects, features and advantages of the exemplary embodiments of the present disclosure will become apparent upon reading the following detailed description of the exemplary embodiments of the present disclosure, when taken in conjunction with the appended claims.

### SUMMARY

In one aspect, a cooling system includes a sump area configured to hold a dielectric fluid, a bath area configured to receive a computer component, a first filter, a second filter, and a pump configured to draw the dielectric fluid from the sump area, pass the dielectric fluid through the first filter or the second filter, and deliver the dielectric fluid to the bath area. The bath area is configured to hold the dielectric fluid.

In another aspect, which may be combined with any other aspect, the first filter and the second filter are positioned in the sump area.

In another aspect, which may be combined with any other aspect, a pH sensor is fluidly connected to the second filter. The pH sensor is configured to indicate a pH of the dielectric fluid flowing through the second filter.

In another aspect, which may be combined with any other aspect, the first filter includes a first housing and a first spout extending from the first housing. The second filter includes a second housing and a second spout extending from the second housing. The pump is configured to deliver the dielectric fluid to the bath area through the first spout or the second spout.

In another aspect, which may be combined with any other aspect, the pump is configured to direct the dielectric fluid through at least one of the first filter or the second filter when the computer component is placed in the bath area.

In another aspect, which may be combined with any other aspect, a cooling system includes a vessel having a sump area and a bath area. The bath area is configured to receive a computer component. The bath area and the sump area are configured to hold a dielectric fluid. The cooling system also includes a first filter, a second filter, and a pump configured to move the dielectric fluid through the cooling system. During a threshold period of time, the pump is configured to draw the dielectric fluid from the sump area, pass the dielectric fluid through the first filter, and deliver the dielectric fluid to the bath area. After the threshold period of time, the pump is configured to draw the dielectric fluid from the sump area, pass the dielectric fluid through the second filter, and deliver the dielectric fluid to the bath area.

In another aspect, which may be combined with any other aspect, a valve is in fluid communication with the pump, a first pipe fluidly connects the valve and the first filter, and a second pipe fluidly connects the valve and the second filter.

In another aspect, which may be combined with any other aspect, during the threshold period of time, the valve fluidly connects the pump and the first filter and fluidly isolates the pump from the second filter. After the threshold period of time, the valve fluidly connects the pump and the second filter and fluidly isolates the pump from the first filter.

In another aspect, which may be combined with any other aspect, a pressure sensor is configured to determine a pressure-drop across the first filter.

In another aspect, which may be combined with any other aspect, when the pressure-drop across the first filter is smaller than a threshold, the pump is configured to pass the dielectric fluid through the first filter. When the pressure-drop across the first filter is larger than the threshold, the pump is configured to pass the dielectric fluid through the second filter.

In another aspect, which may be combined with any other aspect, a flow sensor is configured to determine a flow rate across the first filter.

In another aspect, which may be combined with any other aspect, when the flow rate across the first filter is greater than a threshold, the pump passes the dielectric fluid through the first filter. When the flow rate across the first filter is smaller than the threshold, the pump passes the dielectric fluid through the second filter.

In another aspect, which may be combined with any other aspect, a pH sensor is fluidly connected to the second filter. The pH sensor is configured to determine a pH of the dielectric fluid flowing through the second filter after the threshold period of time.

In another aspect, which may be combined with any other aspect, the threshold period of time is fourteen days.

In another aspect, which may be combined with any other aspect, a cooling system includes a vessel having a sump area and a bath area. The bath area is configured to receive a computer component. The bath area and the sump area are configured to hold a dielectric fluid. The cooling system also includes an expandable bellows configured to regulate an interior pressure of the vessel, a filter having a housing and a spout extending from the housing, and a pump configured to draw the dielectric fluid from the sump area, pass the dielectric fluid through the filter, and deliver the dielectric fluid to the bath area through the spout.

In another aspect, which may be combined with any other aspect, a door is selectively coupled to the vessel. The door is movable between an opened position and a closed position. The door provides access to the vessel in the opened position and seals against the vessel in the closed position.

In another aspect, which may be combined with any other aspect, the door is coupled to the vessel by a motorized clamp that is configured to move the door between the opened position and the closed position.

In another aspect, which may be combined with any other aspect, the vessel is positioned within a shell, and a shock absorber is positioned between the shell and the vessel.

In another aspect, which may be combined with any other aspect, the shock absorber is an active shock absorber, and a stiffness of the active shock absorber is adjusted based on a stress characteristic imposed on the vessel.

In another aspect, which may be combined with any other aspect, the filter is a first filter, the housing is a first housing, and the spout is a first spout. The cooling system further comprises a second filter having a second housing and a second spout extending from the second housing. The pump is configured to pass the dielectric fluid through the first filter and deliver the dielectric fluid to the bath area through the first spout during a threshold period of time. The pump is configured to pass the dielectric fluid through the second filter and deliver the dielectric fluid to the bath area through the second spout after the threshold period of time.

Other aspects of the disclosure will become apparent by consideration of the detailed description and accompanying drawings.

### BRIEF DESCRIPTION OF THE DRAWINGS

Various embodiments of the present disclosure, together with further objects and advantages, may best be understood by reference to the following description taken in conjunction with the accompanying drawings.

FIG. 1 is a schematic view illustrating features of a liquid immersion cooling system.

FIG. 2 is a schematic view illustrating features of a liquid immersion cooling system.

FIG. 3 is a perspective view illustrating features of a liquid immersion cooling system.

FIG. 4 is a perspective view of the liquid immersion cooling system of FIG. 3 with a portion of a housing removed.

FIG. 5 is a side view of the liquid immersion cooling system of FIG. 3 with the portion of the housing removed.

FIG. 6 is a perspective view of a cross-section of the liquid immersion cooling system taken along line 6-6 in FIG. 3.

FIG. 7 is a perspective view of the liquid immersion cooling system of FIG. 3 with a portion of the housing removed.

FIG. 8 is a cross-sectional view of the liquid immersion cooling system taken along line 8-8 in FIG. 5.

### DETAILED DESCRIPTION

The following description of embodiments provide non-limiting representative examples referencing numerals to particularly describe features and teachings of different aspects of the present disclosure. The embodiments described should be recognized as capable of implementation separately, or in combination, with other embodiments from the description of the embodiments. A person of ordinary skill in the art reviewing the description of embodiments should be able to learn and understand the different described aspects of the disclosure. The description of embodiments should facilitate understanding of the disclosure to such an extent that other implementations, not specifically covered but within the knowledge of a person of skill in the art having read the description of embodiments, would be understood to be consistent with an application of the disclosure.

In one example embodiment, an immersion cooling system or a vessel can include a bath area, a sump area, a computing device, a robot, a pressure control system, a temperature control system, and a management system. The vessel can be a pressure controlled tank maintained at the atmospheric pressure (or within a range thereof). The computing device can be immersed in a dielectric fluid in the bath area of the vessel. The computing device can be connected to a network and perform various processing tasks while immersed in the dielectric fluid. The vessel can include a lid for accessing the bath area, the computing device and the sump area. The vessel can be fluidly coupled to the pressure control system. The robot can lift the computing device from the bath area of the vessel when the lid is open. The robot can place the lifted computing device in a magazine provided for storage of computing devices or on a vehicle. The robot can also lift a computing device from the magazine (or vehicle) and place it in the place of the computing device that was lifted from the bath area.

In one example embodiment, the vessel can be provided with an amount of dielectric fluid such that the bath area is full of dielectric fluid and there may be an overflow of dielectric fluid in the sump area. A full bath area can ensure that the computing device is fully immersed in the dielectric fluid. The pump can draw the dielectric fluid from the sump area and pass the fluid through a filter. After passing through the filter, the dielectric fluid can return to the bath area. The vessel can include various pipes that couple the sump area, the pump, the filter and the bath area.

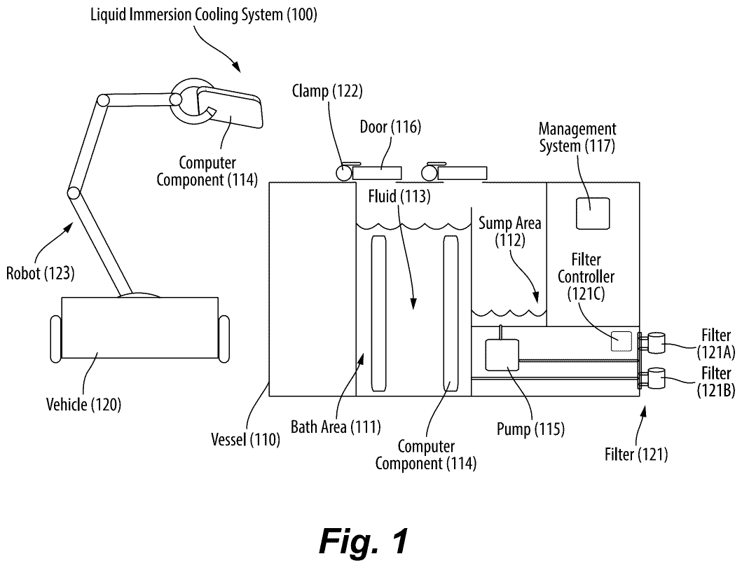

FIG. 1 shows a liquid immersion cooling system 100 including a filter 121. The liquid immersion cooling system 100 can include a vessel 110 (also referred to as a housing 110) and a vehicle 120. The vessel 110 can include a bath area 111, a sump area 112, a fluid 113 (e.g., a dielectric fluid), a computer component 114, a pump 115, the filter 121, a door 116, and a management system 117. The bath area 111 and the sump area 112 hold the fluid 113. The computer component 114 can be submersed in the fluid 113. The vehicle 120 can include a robot 123. The robot 123 can lift the computer component 114 when the door 116 is open and place the computer component 114 on the vehicle 120.

The filter 121 can include one or more cartridge or core. Each cartridge can filter the dielectric fluid 113 for a different type(s) of contaminant, particle, substance, diluent or solute. In one example, one cartridge can include activated carbon (charcoal). In another example, one cartridge can include activated aluminum.

The liquid immersion cooling system can include more than one filter. For example, the liquid immersion cooling system can include a first filter 121A and a second filter 121B. In one example, one or more of the filters 121A and 121B is located outside of the vessel 110. When filters 121A and/or 121B is located outside of the vessel 110, a service personnel can replace one or more of the filters without the need to open the door 116 of the vessel 110. In another example, one or more of the filters 121A and 121B is located inside of the vessel 110.

The filters can be coupled to a filter controller 121C. The filter controller 121C can include a processor, a memory, one or more valves, one or more motors or actuators for controlling the valves, an interface for communicating with the management system 117, one or more pressure readers, and/or one or more flowmeters. The filter controller 121C can (directly or through instructions from the management system 117) direct the fluid 113 to, one, both or neither of the filters 121A and 121B. For example, the filter 121A can be the dedicated filter that is used in the first few minutes after a computer component 114 is placed into the liquid immersion cooling system 100, but the filter 121B can be the dedicated filter that is used after the filter 121A is used for a threshold period of time.

The filter controller 121C can (directly or through instructions from the management system 117) determine when to switch the flow of fluid 113 in between the filters 121A and 121B. For example, the filter controller 121C can conduct a pressure test or a flowrate test and determine whether one, or both of the filters 121A and 121B need replacement. For example, if the fluid 113 pressure-drop across the filter 121A is greater than a threshold (or threshold number) or if the flowrate through the filter 121A is below a threshold number, the filter controller 121C can (directly or through instructions from the management system 117) switch the flow of fluid 113 from the filter 121A to the filter 121B, or direct the flow of fluid 113 to both filters 121A and 121B. The threshold number is related to a build-up of debris and/or contaminants in the filter 121A, 121B. The threshold number can be any suitable number that defines a point at which the filter 121A, 121B is unsuitable for use and should be replaced.

In some examples, when a vessel 110, e.g., through the management system 117, receives instruction that a computer component 114 needs to be replaced or a new computer component 114 is being added to the vessel 110, the management system 117 can provide a signal to the filter controller 121C to execute a replacement routine once the computer component 114 is added to the vessel 110. In practice, most debris and contamination is introduced into the vessel 110 when the computer component 114 is added to the vessel 110. Accordingly, when the computer component 114 is added, the filter 121A can filter the initial debris and contamination from the fluid 113, and after a threshold period of time, the filter controller 121C can switch the flow of fluid from filter 121A to filter 121B. The threshold period of time can be, for example, fourteen days, ten days, seven days, or any other suitable amount of time to sufficiently remove the initial debris and contamination from the fluid 113.

The filter can include a PH indicator. Maintaining a neutral PH environment is important in maintaining a good operating state for the computer component deployed in the fluid. The indicator can be in contact with the dielectric fluid and change color if the dielectric fluid becomes acidic. In one example, the indicator can comprise phenolphthalein. In one example, the filters 121A and 121B each has a PH indicator. The filters 121A and 121B can be placed outside of the vessel 110. In this example, each of the filters 121A and 121B can include a color indicator which is visible outside of the vessel 110.

The filter can include a color detection sensor, which can detect a change in color in the indicator and transmit a signal to the management system (or another system) if a change in color of the indicator is detected. In one example, the indicator can be disposed in a container or chamber including a glass shield. As such, a change in color of the indicator can be visible outside of the container. A camera can be disposed within a vicinity of the container. The camera can take a photo of the indicator (behind the glass shield) and transmit the photo to the management system. If the management system (or a user of the system) detects a change in the color of the indicator (using data provided by the camera or the color sensor), the management system can trigger remedial action, e.g., notify a maintenance system or shutdown the system. In one example, a change in the color of the indicator is visible outside of the vessel 110, e.g., when the filters 121A and 121B are placed outside of the vessel 110.

In one example, the liquid immersion cooling system 100 can include one or more doors 116. Each door 116 is movable between an opened position and a closed position. In the opened position, the door 116 provides access into the vessel 110. In the closed position, the door 116 seals against the vessel 110 to prevent access into the vessel 110. Each door 116 can correspond to a predetermined number of computer components 114. In one example, each door 116 can correspond to one set of computer components 114 minimizing the compute exposure to the external environment outside the vessel 110.

In one example, each door 116 can be secured to and seals against the vessel 110 using a clamp, e.g., a toggle clamp 122. A toggle clamp 122 can provide for easy access to the vessel 110. In this example, a seal can be placed in between the door and the vessel 110 to maintain a consistent internal operating environment. In one example, the clamp can be motorized and operate using signals received from the management system 117. In one example, the clamp can allow for opening of the door 116 only when it receives authorization from the management system 117. In one example, the management system 117 instructs the clamp to open only when a service person provides a password or scans an RFID card.

In one example, the immersion cooling system 100 can be placed on a mobile body. While on the move, the vessel 110 can receive various forms of mechanical stress. As such, one or more elastic mechanisms can be provided to minimize the stress on the vessel 110 and the components thereof.

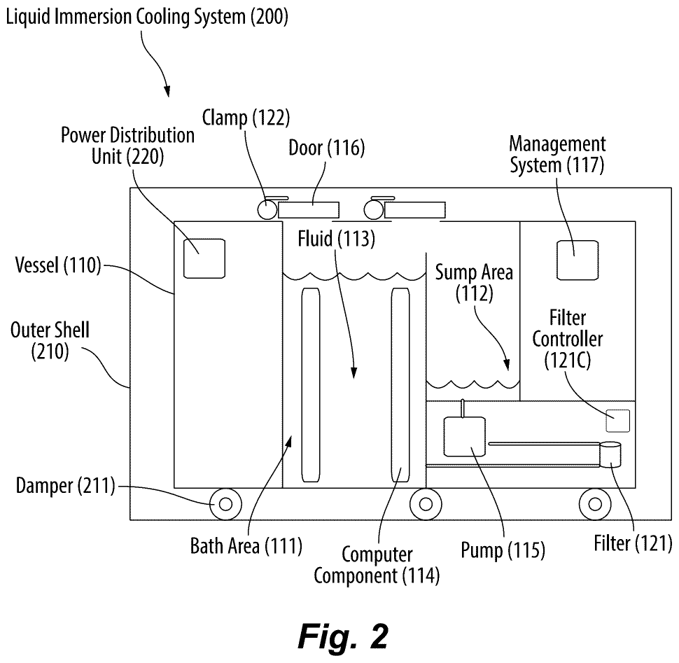

FIG. 2 illustrates a liquid immersion cooling system that includes features combinable with the cooling system 100 shown in FIG. 1. Components of the liquid immersion cooling system 200 are labeled the same as like components of the liquid immersion cooling system 100.

In one example, the vessel 110 can be placed in an outer shell 210. In one example, various elastic mechanisms can be provided in between the outer shell 210 and the vessel 110. For example, the liquid immersion cooling system 200 can include one or more dampers 211 between the outer shell 210 and the vessel 110. In one example, the liquid immersion cooling system 200 can include one or more springs in between the shell 210 and the vessel 110.

In one example, active shock absorbers can be provided in between the shell 210 and the vessel 110. An active shock absorber can be an electronically controlled shock absorber that is able to change the shock absorber behavior depending on the stress characteristics. For example, a stiffness of the active shock absorber can be adjusted to change the performance of the active shock absorber. In one example, the liquid immersion cooling system 200 can include one or more sensors which can determine the movement of the vessel and the stress characteristic imposed on the vessel, e.g., speedometer and accelerometer. In one example, based on the sensor reading, the management system 117 can determine the stress characteristic, and in response, provide various signals to the active shock absorbers to minimize damage to the vessel 110 and the components therein.

In one example, the immersion cooling system 200 can include a power distribution unit 220. The power distribution unit 220 can operate as a switch in the system. For example, the power distribution unit 220 can allow for turning the power of the immersion cooling system 200 on and off at zero current. In one example, the power distribution unit 220 can eliminate voltage spikes. The power distribution unit 200 supplies power to the compute load and the control system. The power distribution unit 200 is configurable for various different input voltages both single phase and three phase. The power distribution unit 200 is compatible for at least both 50and 60 Hz. The power distribution unit 200 can also be configured for single or redundant power input sources. The power distribution unit 200 consists of an input power, a main power disconnect, a power disconnect/interrupt device per server/leg (fuse or breaker), and a relay per server/leg that can be controlled through the unit controller.

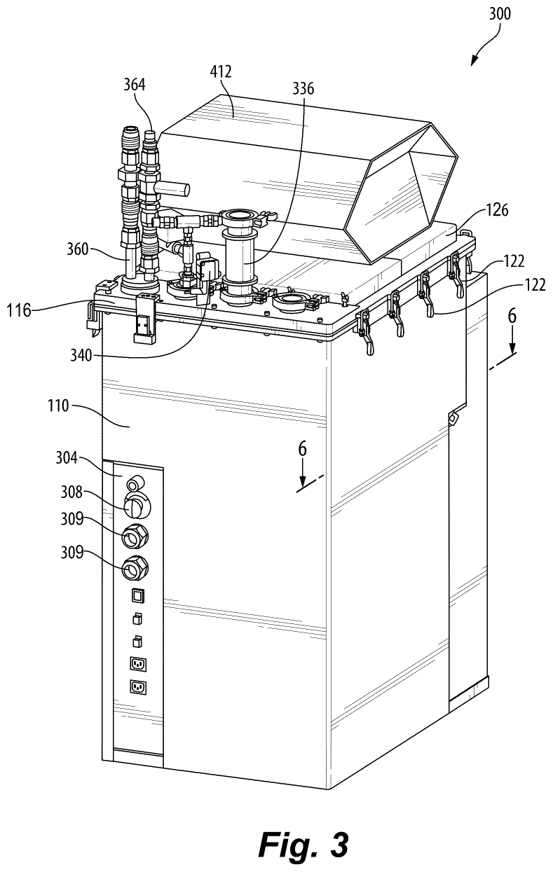

FIGS. 3-8 illustrate a liquid cooling system 300. Components of the liquid cooling system 300 are labeled the same as like components of the liquid cooling systems 100, 200. Any components or features of the liquid cooling systems 100, 200 described herein can be included in the liquid cooling system 300. Similarly, any components or features of the liquid cooling system 300 described herein can be in either liquid cooling system 100, 200.

With reference to FIG. 3, the liquid cooling system 300 includes a control panel 304. The illustrated control panel 304 is recessed relative to an outer surface of the vessel 110. The control panel 304 includes a shut-off switch 308 and connectivity ports 309 to allow local management and control of the liquid cooling system 300. The shut-off switch 308 can, for example, be actuated to disconnect power to the liquid cooling system 300. The control panel 304 can be connected to, for example, the management system 117 and/or the power distribution unit 220 (FIG. 2).

With continued reference to FIG. 3, the door 116 is secured to the vessel 110 using a plurality of the clamps 122. The clamps 122 can be positioned about an entire perimeter of the vessel 110. Alternatively, the clamps 122 can be positioned on only a select number of sides of the vessel 110. In the illustrated, the liquid cooling system 300 includes clamps 122 extending along three sides of the vessel 110.

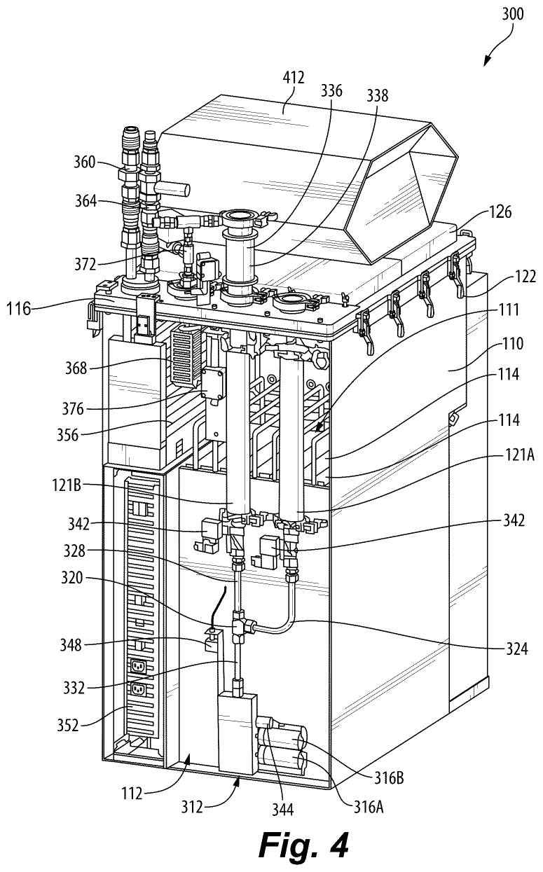

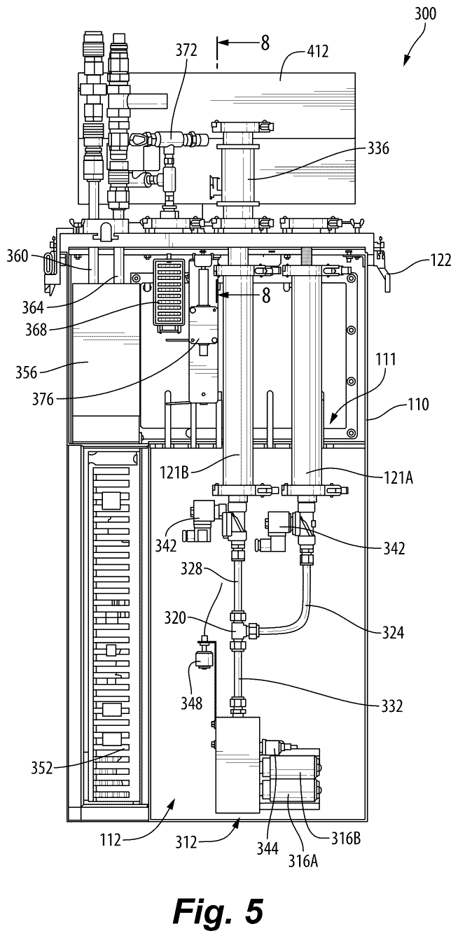

With reference to FIGS. 4 and 5, the first and second filters 121A, 121B are fluidly connected to a pump system 312. The pump system 312 pumps the fluid 113 from the sump area 112, through the first filter 121A or the second filter 121B, and to the bath area 111. The pump system 312 includes a first pump 316A. The pump system 312 can also include a second pump 316B. The second pump 316B can be a redundant pump that is at rest during operation of the first pump 316A and is selectively operated following a failure of the first pump 316A. In some examples, the pump system 312 may include only the first pump 316A.

With continued reference to FIGS. 4 and 5, a valve 320 (e.g., a three-way valve) selectively fluidly connects the pump system 312 to either the first filter 121A or the second filter 121B. As such, the valve 320 fluidly isolates the pump system 312 from either the first filter 121A or the second filter 121B. The first filter 121A is connected to the valve 320 by a first pipe 324, the second filter 121B is connected to the valve 320 by a second pipe 328, and the valve 320 is connected to the pump system 312 by a third pipe 332. The valve 320 is adjustable by, for example, the filter controller 121C, to fluidly connect the pump system 312 with either the first filter 121A through the first pipe 324 or the second filter 121B through the second pipe 328.

In some examples, the pump system 312, the valve 320, and the first, second, and third pipes 324, 328, 332 are entirely positioned within the sump area 112 and the first filter 121A and the second filter 121B are partially positioned within the sump area 112. In other examples, each of the pump system 312, the valve 320, the first, second, and third pipes 324, 328, 332, the first filter 121A, and the second filter 121B can be positioned in any suitable position within or outside the vessel 110 to move the fluid 113 from the sump area 112 to the bath area 111.

With continued reference to FIGS. 4 and 5, the cooling system 300 includes a PH indicator 336. The illustrated PH indicator 336 is connected to the second filter 121B. The PH indicator can be in contact with the fluid 113 and change color if the fluid 113 becomes acidic. The PH indicator 336 includes a glass shield 338. The color of the PH indicator 336 is visible through the glass shield 338. A camera or sensor 340 (shown in FIG. 3) can be positioned adjacent the PH indicator 336, which can detect a change in color in the PH indicator 336 and transmit a signal to the management system 117 (or another system) if a change in color of the PH indicator is detected. In other examples, one PH indicator 336 can be connected to both the first and second filters 121A, 121B.

The cooling system 300 can include a flow control valve 342 coupled to each of the first and second filters 121A, 121B. Each flow control valve 342 can adjust a flow of the fluid 113 through the respective first or second filter 121A, 121B. Each flow control valve 342 can additionally or alternatively monitor a flow rate of the fluid 113 through the respective first or second filter 121A, 121B. In some examples, the flow control valves 342 can be coupled to the first and second pipes 324, 328, respectively, instead of being coupled to the first and second filters 121A, 121B as shown in FIG. 4.

The cooling system 300 can include a pressure sensor 344 connected to the pump system 312 and/or the third pipe 332. The pressure sensor 344 can indicate if the pump system 312 is operating properly or if there is a blockage in, for example, the first or second filter 121A, 121B. For example, the pressure sensor 344 may identify an increasing back pressure when the first or second filter 121A, 121B is ready to be replaced.

With continued reference to FIGS. 4 and 5, the cooling system 300 includes a float sensor 348. The illustrated float sensor 348 is positioned in the sump area 112 adjacent the pump system 312. The float sensor 348 indicates a level of the fluid 113 within the sump area 112. The level of the fluid 113 can be used to, for example, determine if the pump system 312 is properly pumping the fluid 113 from the sump area 112 to the bath area 111.

With continued reference to FIGS. 4 and 5, the cooling system 300 includes a control system 352. The control system 352 is positioned within the vessel 110 adjacent the bath area 111 and the sump area 112. The control system 352 can include, for example, the management system 117, the filter controller 121C, the power distribution unit 220, and any other components that control the operation of the cooling system 300. The control system 352 is connected to the control panel 304.

The cooling system 300 includes a condenser 356. The condenser 356 is circulates a coolant such as water to cool down the fluid 113 when the fluid is in a liquid state and/or a gaseous state. The illustrated condenser 356 is positioned above the control system 352. The condenser 356 is connected to a coolant inlet 360 and a coolant outlet 364. The coolant flows into the condenser 356 through the coolant inlet 360, and the coolant flows out of the condenser 356 through the coolant outlet 364. The coolant inlet 360 and the coolant outlet 364 each extend within the vessel 110 and outside of the vessel 110. A temperature sensor can be connected to the coolant inlet 360. The temperature sensor can measure a temperature of the coolant flowing into the condenser 356 to, for example, indicate if the condenser 356 is receiving coolant at a temperature sufficient to cool down the fluid 113 in the cooling system 300. In other examples, the cooling system 300 can have temperature sensors connected to other components of the cooling system 300 to monitor the operating state of the cooling system 300. A flow sensor can be connected to the coolant outlet 364. The flow sensor can measure a flow rate of the coolant flowing out of the condenser 356 to, for example, indicate if there is a blockage within the condenser 356 that inhibits performance of the condenser 356. In other examples, the cooling system 300 can have flow sensors connected to other components of the cooling system 300 to monitor the operating state of the cooling system 300.

The cooling system 300 includes a desiccant 368 positioned within the vessel 110. The desiccant 368 removes water vapor from inside the vessel 110. The desiccant 368 is connected to a pressure relief valve 372. The illustrated pressure relief valve 372 is positioned outside of the vessel 110. Air enters or exits the vessel 110 through the pressure relief valve 372. When air enters the vessel 110 through the pressure relief valve 372, the air flows through the desiccant 368 to prevent humidity from entering the vessel 110.

The cooling system 300 includes a humidity sensor 376. The humidity sensor 376 detects the amount of water vapor in the vessel 110. The humidity sensor 376 can send a signal to the control system 352. Excessive humidity can be undesirable within the vessel 110 and can damage the computer components 114. As such, the control system 352 can, for example, alert a user if the humidity within the vessel 110 reaches a critical level.

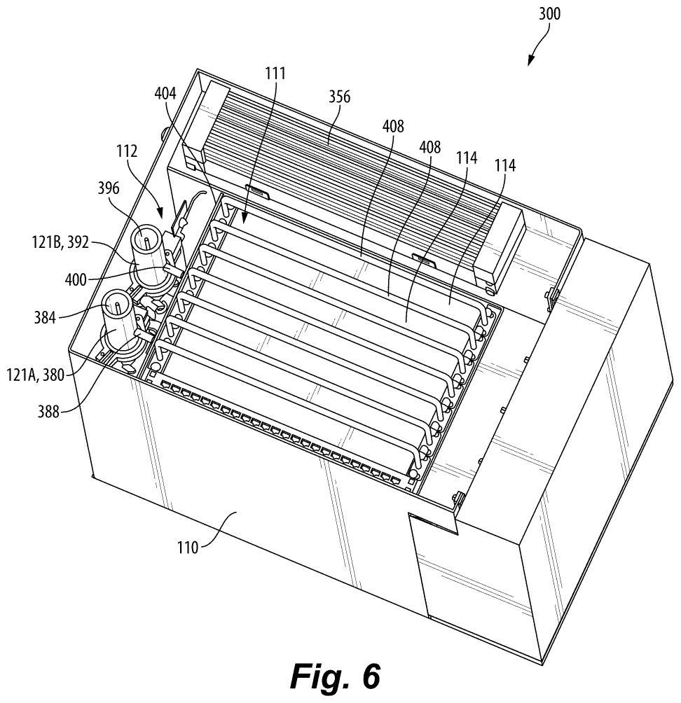

With reference to FIG. 6, the first filter 121A includes a first housing 380 and a first cartridge 384 positioned within the first housing 380. The first filter 121A also includes a first spout 388 extending from the first housing 380. The second filter 121B includes a second housing 392 and a second cartridge 396 positioned within the second housing 392. The second filter 121B also includes a second spout 400 extending from the second housing 392. Depending on which filter 121A, 121B is in use, fluid 113 enters the first or second filter 121A, 121B, passes through the respective first or second cartridge 384, 396, then exits the first or second filter 121A, 121B through the respective first or second spout 388, 400.

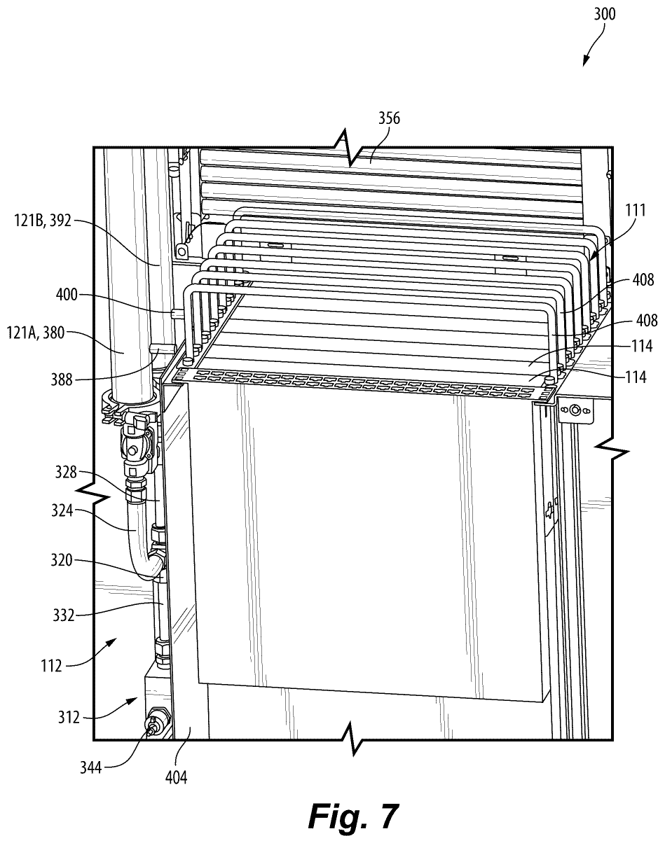

With reference to FIG. 7, the first and second spouts 388, 400 are positioned above a wall 404 that separates the bath area 111 and the sump area 112. The first and second spouts 388, 400 can be, for example, one inch, two inches, etc. above the wall 404. As such, the fluid 113 exits the first and second spouts 388, 400 and enters the bath area 111. In some examples, the first and second spouts 388, 400 extend over the wall 404, such that an outlet of each of the first and second spouts 388, 400 is positioned above the bath area 111. In other examples, the first and second spouts 388, 400 can have any suitable length and extend from any portion of the respective first and second housings 380, 392 to direct the fluid 113 into the bath area 111.

With continued reference to FIG. 7, each computer component 114 includes a handle 408. Each handle 408 can assist with removing the respective computer component 114 from the bath area 111 and/or inserting the respective computer component 114 into the bath area 111.

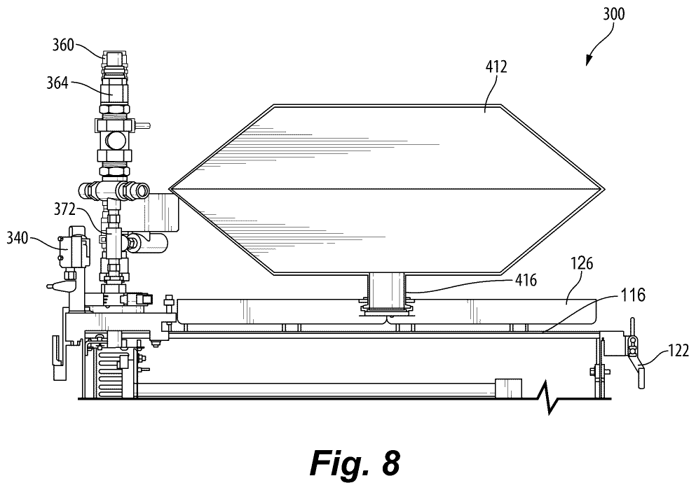

With reference to FIG. 8, the liquid cooling system includes a bellows 412. The bellows 412 is positioned on a side of the door 116 opposite the vessel 110. The bellows 412 is fluidly connected with an inside of the vessel 110 through a channel 416 extending through the door 116. The bellows 412 regulates an interior pressure of the vessel 110. As pressure fluctuates within the vessel 110, the bellows 412 can expand or contract to adjust for the pressure fluctuations such that a relatively constant pressure is maintained within the vessel 110. For example, the bellows 412 may allow the pressure within the vessel 110 to remain at or near atmospheric pressure (i.e., one atmosphere). The fluid 113 may enter the bellows 412 in a gaseous state and then condense within the bellows 412. The inside of the bellows 412 and/or bellows support plate 126 can include a structure (e.g., a ramp structure) to direct the condensed fluid 113 back into the vessel 110. The bellows 412 can be composed of a non-rigid material such as mylar.

During assembly of the cooling system 300, the door 116 is moved to the opened position, and the computer components 114 are placed within the bath area 111 and submerged in the fluid 113. Debris and/or contamination may enter the vessel 110 as the computer components 114 are placed in the vessel 110. The door 116 is then moved to the closed position.

During operation, the computer components 114 heat up (i.e., increase in temperature), which causes the fluid 113 in the bath area 111 to heat up. As the fluid 113 heats up, the fluid 113 may boil. Some of the fluid 113 may spill over the wall 404 and flow into the sump area 112. Some of the fluid 113 may evaporate and subsequently condense by, for example, the condenser 356. The condensed fluid 113 may fall into the bath area 111 or the sump area 112. The fluid 113 in the sump area 112 is then pumped back into the bath area 111. The pump system 312 draws the fluid 113 from the sump area 112 and into the third pipe 332. The pump system 312 pushes the fluid 113 through the valve 320 and then into the first filter 121A through the first pipe 324. The fluid 113 flows through the first filter 121A and then exits the first filter 121A through the first spout 388. The fluid 113 is then delivered to the bath area 111. This process repeats during the threshold period of time.

After the threshold period of time, the debris and/or contamination that entered the vessel 110 during assembly has been captured by the first filter 121A. The filter controller 121C adjusts the valve 320 to direct the fluid 113 into the second pipe 328 instead of the first pipe 324. The pump system 312 then pumps the fluid 113 from the sump area 112, through the third pipe 332, the valve 320, the second pipe 328, and into the second filter 121B. The fluid 113 flows through the second filter 121B and then exits the second filter 121B through the second spout 400. The fluid 113 is then delivered to the bath area 111. This process is repeated until the second filter 121B requires replacement. The second filter 121B has a lifespan much longer than the threshold period of time, e.g., six months, one year, two years, or more.

Although some embodiments of the present disclosure are described in connection with exemplary dual-phase immersion cooling systems, one of ordinary skill in the art recognizes that these same teachings can be applied to single-phase immersion cooling systems as well.

In the preceding specification, various embodiments have been described with references to the accompanying drawings. It will, however, be evident that various modifications and changes may be made thereto, and additional embodiments may be implemented, without departing from the broader scope of the disclosure as set forth in the claims that follow. The specification and drawings are accordingly to be regarded as an illustrative rather than restrictive sense.

What is claimed is:

1. A cooling system comprising:
a sump area configured to hold a dielectric fluid;
a bath area configured to receive a computer component, the bath area configured to hold the dielectric fluid;
a first filter;
a second filter; and
a pump configured to draw the dielectric fluid from the sump area, pass the dielectric fluid through the first filter or the second filter, and deliver the dielectric fluid to the bath area.

2. The cooling system of claim 1, wherein the first filter and the second filter are positioned in the sump area.

3. The cooling system of claim 1, further comprising a pH sensor fluidly connected to the second filter, wherein the pH sensor is configured to indicate a pH of the dielectric fluid flowing through the second filter.

4. The cooling system of claim 1, wherein
the first filter includes a first housing and a first spout extending from the first housing,
the second filter includes a second housing and a second spout extending from the second housing, and
the pump is configured to deliver the dielectric fluid to the bath area through the first spout or the second spout.

5. The cooling system of claim 1, wherein the pump is configured to direct the dielectric fluid through the first filter or the second filter when the computer component is placed in the bath area.

6. A cooling system comprising:
a vessel including a sump area and a bath area, the bath area configured to receive a computer component, the bath area and the sump area configured to hold a dielectric fluid;
a first filter;
a second filter; and
a pump configured to move the dielectric fluid through the cooling system,
wherein, during a threshold period of time, the pump is configured to draw the dielectric fluid from the sump area, pass the dielectric fluid through the first filter, and deliver the dielectric fluid to the bath area, and
wherein, after the threshold period of time, the pump is configured to draw the dielectric fluid from the sump area, pass the dielectric fluid through the second filter, and deliver the dielectric fluid to the bath area.

7. The cooling system of claim 6, further comprising
a valve in fluid communication with the pump,
a first pipe fluidly connecting the valve and the first filter, and
a second pipe fluidly connecting the valve and the second filter.

8. The cooling system of claim 7, wherein during the threshold period of time, the valve fluidly connects the pump and the first filter and fluidly isolates the pump from the second filter, and wherein after the threshold period of time, the valve fluidly connects the pump and the second filter and fluidly isolates the pump from the first filter.

9. The cooling system of claim 6, further comprising a pressure sensor configured to determine a pressure-drop across the first filter.

10. The cooling system of claim 9, wherein when the pressure-drop across the first filter is smaller than a threshold, the pump is configured to pass the dielectric fluid through the first filter, and wherein when the pressure-drop across the first filter is larger than the threshold, the pump is configured to pass the dielectric fluid through the second filter.

11. The cooling system of claim 6, further comprising a flow sensor configured to determine a flow rate across the first filter.

12. The cooling system of claim 11, wherein when the flow rate across the first filter is greater than a threshold, the pump passes the dielectric fluid through the first filter, and wherein when the flow rate across the first filter is smaller than the threshold, the pump passes the dielectric fluid through the second filter.

13. The cooling system of claim 6, further comprising a pH sensor fluidly connected to the second filter, wherein the pH sensor is configured to determine a pH of the dielectric fluid flowing through the second filter after the threshold period of time.

14. The cooling system of claim 6, wherein the threshold period of time is fourteen days.

15. A cooling system comprising:
a vessel including a sump area and a bath area, the bath area configured to receive a computer component, the bath area and the sump area configured to hold a dielectric fluid;
an expandable bellows configured to regulate an interior pressure of the vessel;
a filter having a housing and a spout extending from the housing; and
a pump configured to draw the dielectric fluid from the sump area, pass the dielectric fluid through the filter, and deliver the dielectric fluid to the bath area through the spout.

16. The cooling system of claim 15, further comprising a door selectively coupled to the vessel, wherein the door is movable between an opened position and a closed position, wherein the door provides access to the vessel in the opened position, and wherein the door seals against the vessel in the closed position.

17. The cooling system of claim 16, wherein the door is coupled to the vessel by a motorized clamp that is configured to move the door between the opened position and the closed position.

18. The cooling system of claim 16, wherein the vessel is positioned within a shell, and wherein a shock absorber is positioned between the shell and the vessel.

19. The cooling system of claim 18, wherein the shock absorber is an active shock absorber, and wherein a stiffness of the active shock absorber is adjusted based on a stress characteristic imposed on the vessel.

20. The cooling system of claim 16, wherein
the filter is a first filter,
the housing is a first housing,
the spout is a first spout,
the cooling system further comprises a second filter having a second housing and a second spout extending from the second housing,
the pump is configured to pass the dielectric fluid through the first filter and deliver the dielectric fluid to the bath area through the first spout during a threshold period of time, and
the pump is configured to pass the dielectric fluid through the second filter and deliver the dielectric fluid to the bath area through the second spout after the threshold period of time.
